(19) United States
(12) Patent Application Publication
(10) Pub. No.: US 2021/0011387 A1
(43) Pub. Date: Jan. 14, 2021

(54) METHOD OF FORMING INSULATING LAYER

(71) Applicant: DISCO CORPORATION, Tokyo (JP)

(72) Inventor: Sakae MATSUZAKI, Tokyo (JP)

(21) Appl. No.: 16/915,075

(22) Filed: Jun. 29, 2020

(30) Foreign Application Priority Data
Jul. 9, 2019 (JP) 2019-127516

(51) Int. Cl. G03F 7/40; H01L 21/027; G03F 7/16; G03F 7/039; G03F 7/038; G03F 7/20; G03F 7/32

(52) U.S. Cl. CPC G03F 7/40; H01L 21/0274; G03F 7/162; G03F 7/32; G03F 7/0387; G03F 7/168; G03F 7/2002; G03F 7/039

(57) ABSTRACT

A method of forming an insulating layer on a first interconnect layer formed on a first surface of a wafer includes a step of coating an upper surface of the first interconnect layer and the upper surface of the wafer with a thermosetting resin, a step of modifying predetermined regions of the thermosetting resin into modified resin portions, a step of dissolving the modified resin portions modified in the modifying step with a chemical solution and thereafter removing the dissolved modified resin portions by supplying a cleaning fluid to the wafer, a step of accommodating the wafer into a hermetically sealable chamber, hermetically sealing the chamber, and making the chamber free of oxygen, and a step of heating the wafer accommodated in the chamber that has been made free of oxygen to thermoset the thermosetting resin.

### BACKGROUND OF THE INVENTION

### Field of the Invention

The present invention relates to a method of forming an insulating layer on a first interconnect layer disposed on an upper surface of a wafer.

### Description of the Related Art

There has heretofore been known a technology regarding an interconnect substrate on which semiconductor chips and various electrical parts are mounted and electrical conduction is secured between their electrodes and other parts. The interconnect substrate includes a first interconnect layer, an insulating layer, and a second interconnect layer that are layered on the upper surface of a wafer.

The insulating layer may be made of either an inorganic material called tetraethoxysilane (TEOS) or a resin. In a case where the insulating layer is made of TEOS, an inorganic film of TEOS is formed on the upper surface of the wafer and the first interconnect layer and thereafter coated with a resist, and then, the resist film corresponding to junctions of the first interconnect layer that are to be connected to the second interconnect layer is exposed to light, developed, and etched to remove the inorganic film, thereby forming the junctions. Subsequently, the resist is removed by a chemical solution, and the wafer is cleaned. Therefore, the formation of the inorganic film, the exposure, the development, the etching, and the removal of the resist are necessary, resulting in an increased number of man-hours.

In a case where an insulating layer is made of a resin, as with a method of manufacturing an interconnect substrate disclosed in Japanese Patent Laid-Open No. 2019-041041, a photosensitive thermosetting resin such as polyimide, for example, is applied to an upper surface of a wafer and the first interconnect layer, and regions of the formed resin film corresponding to junctions of the first interconnect layer that are to be connected to a second interconnect layer are modified by being irradiated with light. Then, a liquid for dissolving the thermosetting resin is applied to dissolve the thermosetting resin, thereby removing the thermosetting resin corresponding to the junctions. Thereafter, the wafer is cleaned with a cleaning fluid to remove the liquid for dissolving the thermosetting resin, and the remaining thermosetting resin is thermoset by being heated in a range from 200° C. to 400° C., forming an insulating layer. According to this process, it is possible to form an insulating layer in a shorter period of time than a case where the insulating layer is made of an inorganic film of TEOS.

### SUMMARY OF THE INVENTION

However, when the thermosetting resin is heated to thermoset itself, oxide films tend to be formed on the junctions of the first interconnect layer, so that the first interconnect layer cannot be connected to the second interconnect layer.

It is therefore an object of the present invention to provide a method of forming an insulating layer of a thermosetting resin on a wafer without forming oxide films on junctions of a first interconnect layer that are to be connected to a second interconnect layer.

In accordance with an aspect of the present invention, there is provided a method of forming an insulating layer on a first interconnect layer formed on an upper surface of a wafer, including a coating step of coating an upper surface of the first interconnect layer and the upper surface of the wafer with a photosensitive thermosetting resin, a modifying step of modifying predetermined regions of the photosensitive thermosetting resin into modified resin portions by irradiating the predetermined regions with light, a removing step of dissolving the modified resin portions modified in the modifying step with a chemical solution that is supplied thereto to dissolve the modified resin portions and thereafter removing the dissolved modified resin portions by supplying a cleaning fluid to the wafer, an oxygen-free environment creating step of accommodating the wafer from which the dissolved modified resin portions have been removed in the removing step into a hermetically sealable chamber, hermetically sealing the chamber, and making the chamber free of oxygen, and a thermosetting step of heating the wafer accommodated in the chamber that has been made free of oxygen in the oxygen-free environment creating step to thermoset the photosensitive thermosetting resin, thereby forming an insulating layer.

In the oxygen-free environment creating step, the chamber may be evacuated to be free of oxygen.

In the oxygen-free environment creating step, the chamber may be filled with an inactive gas to be free of oxygen.

In the thermosetting step, the chamber may be heated to heat the wafer, the photosensitive thermosetting resin may be thermoset with the heat of the heated wafer, and the insulating layer may be thereby formed.

In the thermosetting step, the chamber may be made of quartz glass through which an infrared ray passes, an infrared ray may be applied from outside the chamber to the wafer in the chamber to heat the wafer with the applied infrared ray, the photosensitive thermosetting resin may be thermoset with the heat of the heated wafer, and the insulating layer may be thereby formed.

The method of forming an insulating layer on a first interconnect layer formed on an upper surface of a wafer according to the aspect of the present invention is effective to prevent oxide films from being formed on junctions of the first interconnect layer that are to be connected to a second interconnect layer.

In the oxygen-free environment creating step, the chamber is evacuated to make the chamber free of oxygen with ease.

In the oxygen-free environment creating step, the chamber is filled with an inactive gas to make the chamber free of oxygen with ease.

In the thermosetting step, the chamber is heated to heat the wafer, the photosensitive thermosetting resin is thermoset with the heat of the heated wafer, and the insulating layer is thereby formed, so that the photosensitive thermosetting resin can be thermoset in its entirety in a short period of time to form the insulating layer.

In the thermosetting step, the chamber is made of quartz glass through which an infrared ray passes, an infrared ray is applied from outside the chamber to the wafer in the chamber to heat the wafer with the applied infrared ray, and the photosensitive thermosetting resin is thermoset with the heat of the heated wafer, forming the insulating layer, so that, since the chamber itself is not heated, the wafer accommodated in the chamber and having the insulating layer formed by thermosetting the photosensitive thermosetting resin can be moved together with the chamber without the need for cooling the chamber. Accordingly, the entire process of forming the insulating layer is made efficient.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a cross-sectional view of a wafer on which an insulating layer is to be formed;

FIG. 2 is a cross-sectional view of the wafer with a film of photosensitive thermosetting resin formed on an upper surface of a first interconnect layer and an upper surface of the wafer;

FIG. 3 is a cross-sectional view illustrating a manner in which predetermined regions of the film of photosensitive thermosetting resin formed on the wafer are modified by being irradiated with light;

FIG. 4 is a cross-sectional view of the wafer with the modified predetermined regions of the film of photosensitive thermosetting resin;

FIG. 5 is a cross-sectional view illustrating a manner in which the modified resin of the predetermined regions of the film of photosensitive thermosetting resin is dissolved by a chemical solution;

FIG. 6 is a cross-sectional view illustrating a manner in which a cleaning fluid is ejected onto the upper surface of the wafer, removing the chemical solution and the dissolved modified resin of the predetermined regions of the film of photosensitive thermosetting resin;

FIG. 7 is a cross-sectional view illustrating a manner in which the developed wafer is dried by being rotated;

FIG. 8 is a cross-sectional view illustrating a manner in which a chamber housing the wafer therein is evacuated to make itself free of oxygen and heated to heat the wafer, and the photosensitive thermosetting resin is thermoset by the heat of the heated wafer to form an insulating layer; and

FIG. 9 is a cross-sectional view illustrating a manner in which a chamber housing the wafer therein is filled with an inactive gas to make itself free of oxygen, the wafer is heated by an infrared ray, and the photosensitive thermosetting resin is thermoset by the heat of the heated wafer to form an insulating layer.

### DETAILED DESCRIPTION OF THE PREFERRED EMBODIMENTS

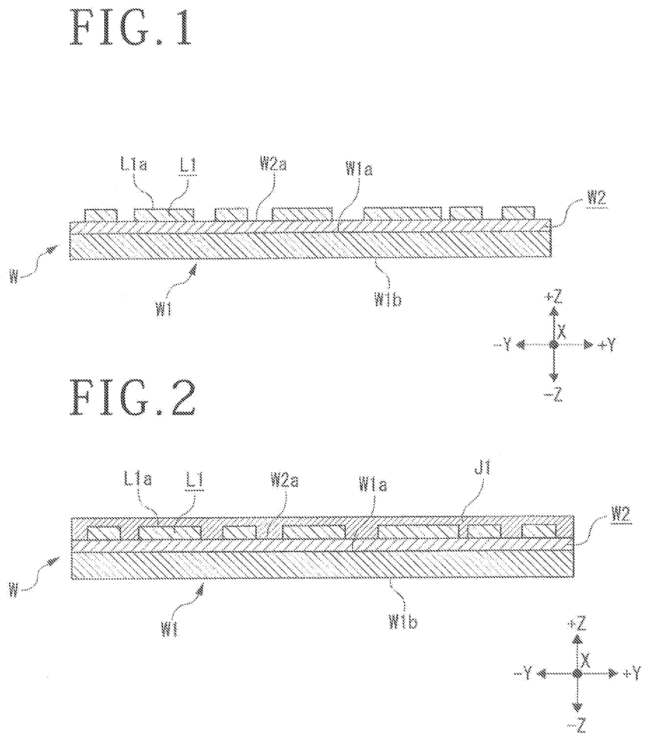

A method of forming an insulating layer on a wafer according to a preferred embodiment of the present invention will be described below with reference to the drawings. As illustrated in FIG. 1, a wafer W has an upper surface W2a with a first interconnect layer L1 formed thereon. The steps of the method of forming an insulating layer on the first interconnect layer L1 on the wafer W will be described below.

The wafer W illustrated in FIG. 1 includes a silicon wafer W1 of a circular profile having an upper surface W1a and an SiO₂ film W2 formed on the entire upper surface W1a as an insulating film having a uniform thickness, for example. The SiO₂ film W2 has an upper surface W2a that acts as the upper surface W2a of the wafer W. The silicon wafer W1 has a lower surface W1b that also acts as a lower surface W1b of the wafer W, for example. The lower surface W1b is protected by a protective tape, not illustrated, affixed thereto.

The first interconnect layer L1 that includes devices, bumps, etc. and is made of a base material of aluminum, for example, is formed over the upper surface W1a of the silicon wafer W1. When semiconductor chips and various electronic parts are mounted on the wafer W, the first interconnect layer L1 functions to secure electrical conduction between their electrodes and other parts. The first interconnect layer L1 includes a plurality of interconnects disposed at spaced intervals over the upper surface W1a of the silicon wafer W1 according to a preset interconnect pattern.

The wafer W is not limited to the illustrated configuration according to the present embodiment, but may include an interconnect substrate made of a base material such as sapphire, glass, or the like and an insulating film such as the SiO₂ film W2 or like and the first interconnect layer L1 layered on the interconnect substrate, for example.

(1) Coating Step

An upper surface L1a of the first interconnect layer L1 on the upper surface W2a of the wafer W and the upper surface W2a of the wafer W are coated with a photosensitive thermosetting resin. Specifically, for example, the wafer W is loaded to a spin coater, not illustrated, and placed on a holding table of the spin coater. While the holding table is being rotated, a photosensitive thermosetting resin J1 in FIG. 2, which may be a positive photosensitive polyimide resin, is dropped in a liquid phase from a liquid supply nozzle onto the wafer W on the rotating holding table, forming a film of the photosensitive thermosetting resin J1 to a uniform thickness entirely on the upper surface L1a of the first interconnect layer L1 and the upper surface W2a of the wafer W. Alternatively, a film of a negative photosensitive polyimide resin may be formed entirely on the upper surface L1a of the first interconnect layer L1 and the upper surface W2a of the wafer W.

The film of the photosensitive thermosetting resin J1, hereinafter referred to as the “photosensitive thermosetting resin film J1” is then dried upon rotation of the holding table that holds the wafer W or by being left to stand for a certain period of time, almost losing its flowability in the liquid phase.

Rather than forming the photosensitive thermosetting resin film J1 to a desired uniform thickness entirely on the upper surface L1a of the first interconnect layer L1 and the upper surface W2a of the wafer W by applying the photosensitive thermosetting resin J in one coating cycle, the photosensitive thermosetting resin J1 in the liquid phase may be applied and dried repeatedly in small amounts in a plurality of coating cycles to form the photosensitive thermosetting resin film J1 entirely on the upper surface L1a of the first interconnect layer L1 and the upper surface W2a of the wafer W to the desired uniform thickness.

The photosensitive thermosetting resin J1 may be applied to the upper surface L1a of the first interconnect layer L1 and the upper surface W2a of the wafer W by a spray coating process or a potting process instead of the spin coating process according to the present embodiment.

(2) Modifying Step

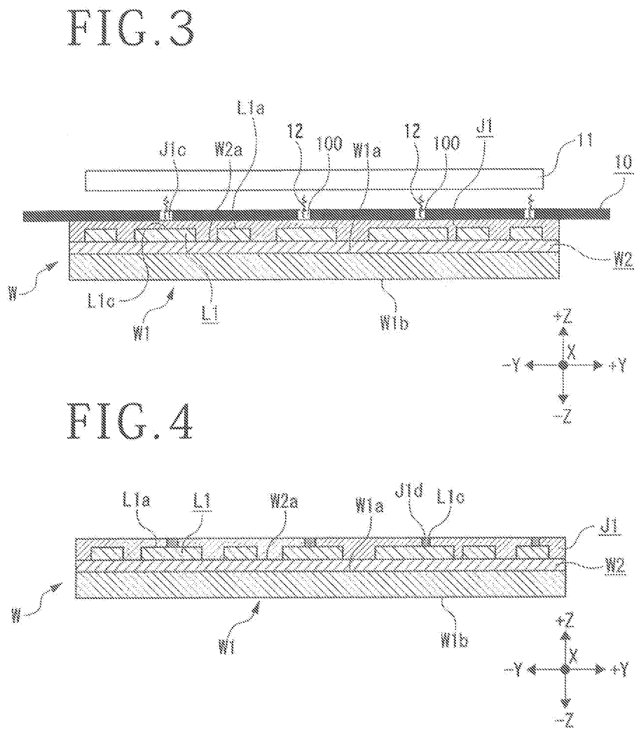

Then, as illustrated in FIG. 3, predetermined regions J1c of the photosensitive thermosetting resin film J1 are modified or exposed to light by being irradiated with light 12. The predetermined regions J1c correspond to respective junctions L1c of the first interconnect layer L1 that to be connected to a second interconnect layer, e.g., respective portions where electrodes are to be formed. Specifically, a light blocking plate 10 that is larger in diameter than the wafer W and that has light transmission slits 100 defined therein in alignment with the predetermined regions J1c of the photosensitive thermosetting resin film J1, for example, is disposed above the wafer W. Then, the light 12 having a predetermined wavelength is applied from light applying means 11 such as an ultraviolet lamp or the like, for example, disposed above the light blocking plate 10 through the light transmission slits 100 to the predetermined regions J1c of the photosensitive thermosetting resin film J1, exposing the regions J1c to the light 12.

As a result, as illustrated in FIG. 4, the predetermined regions J1c of the photosensitive thermosetting resin film J1 are modified into modified resin portions J1d. The modified resin portions J1d are acidic.

(3) Removing Step

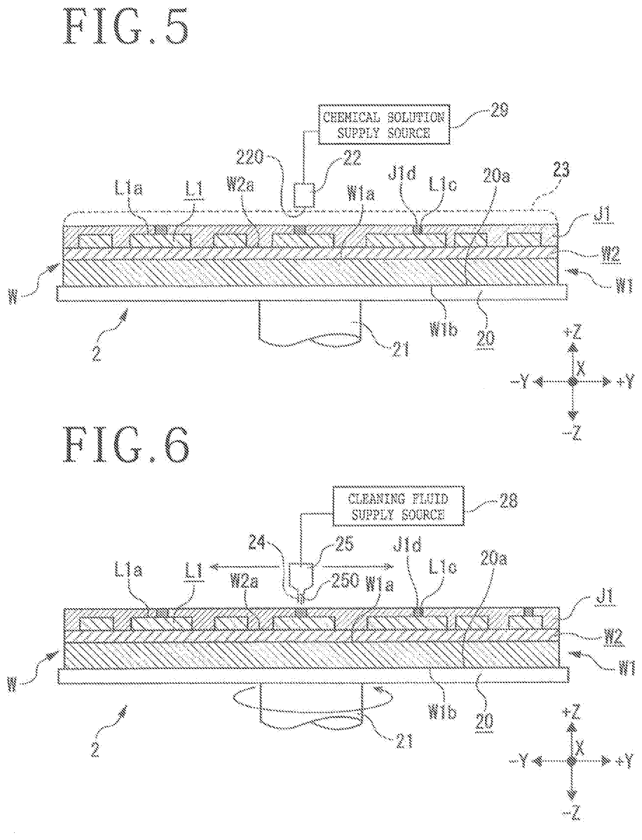

Next, the wafer W is transferred to a developing apparatus 2 illustrated in FIG. 5. The developing apparatus 2 includes a holding table 20 surrounded by a casing, not illustrated. The holding table 20 has a holding surface 20a lying parallel to horizontal directions, i.e., X-axis directions and Y-axis directions, for holding the wafer W under suction thereon. The holding table 20 is rotatable by a rotational shaft 21 about the central axis thereof that extends in Z-axis directions perpendicular to the X-axis directions and the Y-axis directions.

The developing apparatus 2 also includes a chemical solution supply nozzle 22 disposed above the holding table 20 for dropping a chemical solution 23, and a chemical solution supply source 29 held in fluid communication with the chemical solution supply nozzle 22. The chemical solution supply source 29 supplies the chemical solution 23, which is alkaline for dissolving the modified resin portions J1d, to the chemical solution supply nozzle 22. The chemical solution supply nozzle 22 has a supply port 220 defined in a distal end thereof and opening toward the holding surface 20a of the holding table 20. The chemical solution supply nozzle 22 is swingingly movable from a position above the center of the holding table 20 radially outwardly toward a retracted position outside the holding table 20, for example.

The developing apparatus 2 operates as follows: First, the wafer W with the photosensitive thermosetting resin film J1 facing upwardly is placed on the holding surface 20a of the holding table 20 and held under suction thereon. Then, the chemical solution supply nozzle 22 is swung from the retracted position to the position above the center of the holding table 20, where the supply port 220 is positioned above the center of the wafer W. The chemical solution supply source 29 then delivers the chemical solution 23 to the chemical solution supply nozzle 22, which drops an appropriate amount of the chemical solution 23 onto the upper surface of the photosensitive thermosetting resin film J1 on the wafer W. When a prescribed amount of the chemical solution 23 is deposited entirely on the upper surface of the photosensitive thermosetting resin film J1 under surface tension, as illustrated in FIG. 5, the chemical solution supply source 29 stops delivering the chemical solution 23 to the chemical solution supply nozzle 22.

The chemical solution 23 thus applied to the photosensitive thermosetting resin film J1 dissolves the modified resin portions J1d.

As illustrated in FIG. 6, the developing apparatus 2 includes a cleaning fluid ejection nozzle 25 for ejecting a cleaning fluid 24, e.g., pure water, downwardly. The cleaning fluid ejection nozzle 25 is held in fluid communication with a cleaning fluid supply source 28 that delivers the cleaning fluid 24. The cleaning fluid ejection nozzle 25 has an ejection port 250 defined in a distal end thereof and opening toward the holding surface 20a of the holding table 20. The cleaning fluid ejection nozzle 25 is movable from a position above the center of the holding table 20 radially outwardly toward a retracted position outside the holding table 20, for example.

After the chemical solution supply nozzle 22 illustrated in FIG. 5 has been retracted from the position above the wafer W, the cleaning fluid ejection nozzle 25 is swung reciprocably through a predetermined angle, for example, in horizontal directions above the wafer W, as illustrated in FIG. 6. At the same time, the holding table 20 is rotated about the central axis of the rotational shaft 21. The cleaning fluid 24 is ejected from the cleaning fluid ejection nozzle 25 toward the entire upper surface of the photosensitive thermosetting resin film J1, washing away the chemical solution 23 illustrated in FIG. 5 and also the dissolved modified resin portions J1d from the predetermined regions J1c.

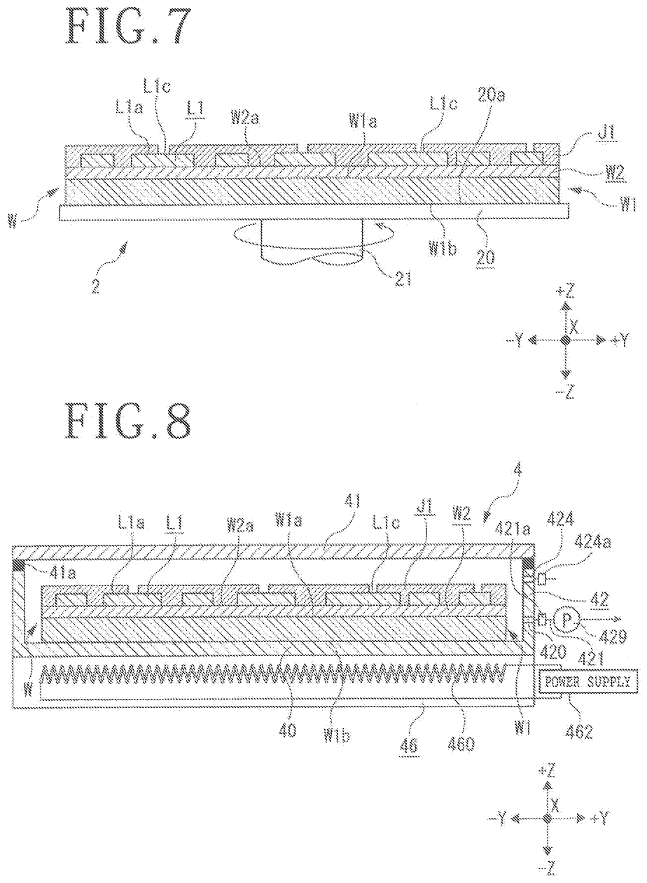

After the upper surface of the photosensitive thermosetting resin film J1 has been cleaned by the cleaning fluid 24 ejected from the cleaning fluid ejection nozzle 25, the cleaning fluid ejection nozzle 25 stops ejecting the cleaning fluid 24. Furthermore, as illustrated in FIG. 7, the holding table 20 is rotated to dry the wafer W.

(4-1) Oxygen-Free Environment Creating Step According to First Embodiment

Next, the wafer W is loaded into a hermetically sealable chamber 4 as illustrated in FIG. 8.

The chamber 4, which is made of stainless steel or the like, includes a bottom plate 40, a top plate 41 spaced from and facing the bottom plate 40, and a side wall 42 connected to the bottom plate 40 and the top plate 41. The chamber 4 is of a low profile having a small height capable of accommodating a single wafer W therein. The chamber 4 is of such a size that an operator can stack a plurality of chambers 4 together, for example.

The top plate 41 of the chamber 4 is detachable from the side wall 42. A rubber packing 41a is disposed between a lower surface of the top plate 41 and an upper end face of the side wall 42 to make the chamber 4 hermetically sealed to a high degree.

The side wall 42 has an evacuation port 420 defined therethrough. A vacuum pump 429 is removably connected to the evacuation port 420 through a pipe 421 having a first opening/closing valve 421a.

The side wall 42 also has a vent port 424 defined therethrough that can selectively be opened and closed by a second opening/closing valve 424a.

The wafer W from which the modified resin portions J1d have been removed in the removing step is accommodated in the chamber 4 with the top plate 41 removed therefrom, as illustrated in FIG. 8. Then, the top plate 41 is put on the side wall 42 with the rubber packing 41a interposed therebetween, making the chamber 4 hermetically sealed.

In an oxygen-free environment creating step according to a first embodiment, the first opening/closing valve 421a is opened, and the second opening/closing valve 424a is closed. Then, the vacuum pump 429 is actuated to evacuate the chamber 4, making the inside of the chamber 4 free of oxygen, or creating a vacuum atmosphere in the chamber 4.

(5-1) Thermosetting Step According to First Embodiment

The chamber 4 that has accommodated the wafer W therein in a hermetically sealed state and has been made free of oxygen is placed on a chamber rest table 46 with a built-in heater 460 illustrated in FIG. 8, for example. The heater 460 that is electrically connected to a power supply 462 is an electrothermal heater including a heating wire or the like, for example. However, the heater 460 is not limited to an electrothermal heater, but may be any heater capable of uniformly heating the chamber 4 within a short period of time. The chamber 4 with the wafer W accommodated therein may be placed on the chamber rest table 46 before being heated, and then evacuated before the chamber rest table 46 is heated. The chamber 4 is evacuated to a vacuum in a range from −85 kPa to −100 kPa.

In a thermosetting step according to the first embodiment, the heater 460 generates heat when it is supplied with electric power from the power supply 462, heating the inside of the chamber 4 that has been placed on the chamber rest table 46 and made free of oxygen to a predetermined temperature. The wafer W accommodated in the chamber 4 is heated in the heated chamber 4, and the photosensitive thermosetting resin J1 is thermoset to form an insulating layer by the heat of the heated wafer W. In the thermosetting step, the vacuum pump 429 may continuously be actuated to keep on evacuating the chamber 4, or after the chamber 4 has been made free of oxygen, the vacuum pump 429 may be inactivated, and the first opening/closing valve 421a may be closed. The photosensitive thermosetting resin J1 is thermoset when heated to a temperature in a range from 230° C. to 400° C.

When the photosensitive thermosetting resin J1 has been thermoset to form an insulating layer on the wafer W, the heater 460 stops heating the chamber 4. While being hermetically sealed and free of oxygen, the chamber 4 is left to stand on the chamber rest table 46 for a predetermined period of time, so that the chamber 4 and the wafer W are naturally cooled.

The vacuum pump 429 is inactivated to stop evacuating the chamber 4, and the second opening/closing valve 424a is opened to vent the chamber 4 to the atmosphere through the vent port 424. The top plate 41 can now be detached.

The wafer W is cooled until no reaction will occur to form oxide films on the junctions L1c of the first interconnect layer L1 to be connected to a second interconnect layer, i.e., the wafer W is cooled to normal temperature, even if the wafer W is in contact with the outside air. The cooled wafer W is then taken out of the chamber 4 and delivered to a sputtering apparatus, not illustrated, for forming a second interconnect layer on the wafer W.

The chamber 4 may not be cooled on the chamber rest table 46, but may instead be added to and cooled in a stack of similar chambers 4 that accommodate therein respective wafers W with insulating layers formed thereon. The stack of chambers 4 thus cooled together is preferable as it is a space saver and allows the chamber rest table 46 to be used for supporting another chamber 4 thereon, avoiding a reduction in the working efficiency which would otherwise be lowered in a case where the chamber rest table 46 is occupied to cool the wafer W thereon.

As described above, the method of forming an insulating layer on the first interconnect layer L1 on the upper surface W2a of the wafer W includes the coating step of coating the upper surface L1a of the first interconnect layer L1 and the upper surface W2a of the wafer W with the photosensitive thermosetting resin J1, the modifying step of modifying the predetermined regions J1c of the photosensitive thermosetting resin J1 into modified resin portions J1d by irradiating the predetermined regions J1c with the light 12, the removing step of dissolving the modified resin portions J1d with the chemical solution 23 that is supplied thereto to dissolve the modified resin portions J1d and thereafter removing the dissolved modified resin portions J1d by supplying the cleaning fluid 24 to the wafer W, the oxygen-free environment creating step of accommodating the wafer W after the removing step into the hermetically sealable chamber 4, hermetically sealing the chamber 4, and making the chamber 4 free of oxygen, and the thermosetting step of heating the wafer W accommodated in the chamber 4 that has been made free of oxygen in the oxygen-free environment creating step to thermoset the photosensitive thermosetting resin J1, thereby forming an insulating layer. The method is effective to prevent oxide films from being formed on the junctions L1c of the first interconnect layer L1 that are to be connected to the second interconnect layer. Since the insulating layer is formed on the single wafer W accommodated in the chamber 4, the chamber 4 is easily kept free of oxygen until the wafer W is cooled to normal temperature after the photosensitive thermosetting resin J1 has been thermoset.

In the oxygen-free environment creating step, according to the first embodiment, as the chamber 4 is evacuated to make itself free of oxygen, the chamber 4 can easily be made free of oxygen within a short period of time.

In the thermosetting step, according to the first embodiment, the chamber 4 is heated to heat the wafer W, and the photosensitive thermosetting resin J1 is thermoset by the heat of the wafer W that is heated, forming the insulating layer. Therefore, the photosensitive thermosetting resin J1 can be thermoset in a short period of time, forming the insulating layer.

The second interconnect layer is formed on the wafer W that has been taken out of the chamber 4 according to any known processes. For example, a plasma is formed in a vacuum atmosphere in an evacuated chamber in a sputtering apparatus, not illustrated, and metal particles of aluminum or the like ejected from a sputtering target are deposited as a sputtered film on the first interconnect layer L1 of the wafer W with the insulating layer interposed therebetween. Thereafter, the sputtered film is coated with a resist, and the circuit pattern is developed and etched by way of wet etching or dry etching, forming a second interconnect layer.

(4-2) Oxygen-Free Environment Creating Step According to Second Embodiment

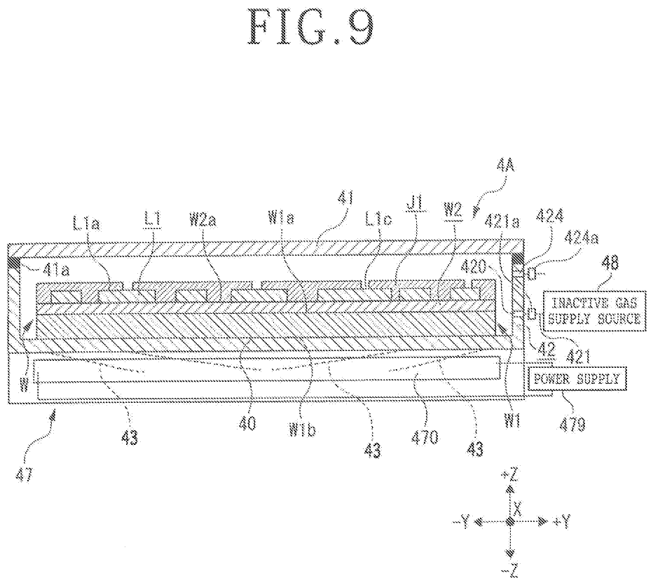

In an oxygen-free environment creating step according to a second embodiment, a chamber 4A illustrated in FIG. 9 is filled with an inactive gas to make itself free of oxygen. The chamber 4A itself is similar in structure to the chamber 4 illustrated in FIG. 8. Those parts illustrated in FIG. 9 which are identical to those of the chamber 4 illustrated in FIG. 8 are denoted by identical reference characters and will not be described in detail below. As illustrated in FIG. 9, the evacuation port 420 is connected through the pipe 421 to an inactive gas supply source 48. According to the second embodiment, the inactive gas supply source 48 stores a nitrogen gas, for example, though it may store an argon gas. The chamber 4A may have a relief valve, not illustrated, for preventing an excessive pressure from building up therein when the inactive gas is introduced from the inactive gas supply source 48 into the chamber 4A, for example.

The chamber 4A may be identical in structure to the chamber 4 illustrated in FIG. 8.

In a case where the chamber 4A is filled with the inactive gas to make itself free of oxygen, a heater may be disposed on an upper side of the chamber 4A for heating the photosensitive thermosetting resin J1.

For example, the chamber 4A is made of quartz glass that can transmit an infrared ray 43 (see FIG. 9) therethrough, unlike the chamber 4 illustrated in FIG. 8. As illustrated in FIG. 9, the chamber 4A is placed on a chamber rest table 47 with a built-in infrared heater 470 such as a ceramic heater or the like capable of radiating a far-infrared ray, for example.

The wafer W from which the modified resin portions J1d have been removed in the removing step is accommodated in the chamber 4A illustrated in FIG. 9 with the top plate 41 removed therefrom. Then, the top plate 41 is put on the side wall 41 with the rubber packing 41a interposed therebetween, making the chamber 4 hermetically sealed. The first opening/closing valve 421a is opened, and the second opening/closing valve 424a is opened. Then, the inactive gas supply source 48 supplies the nitrogen gas to the chamber 4A while controlling the supply rate of the nitrogen gas, replacing the oxygen in the chamber 4A with the nitrogen gas. Specifically, the nitrogen gas introduced into the chamber 4A discharges the oxygen out of the chamber 4A through the vent port 424, making any residual oxygen in the chamber 4A infinitely nil. After sufficiently creating a nitrogen atmosphere in the chamber 4A by performing the above nitrogen purge for a predetermined period of time, the inactive gas supply source 48 stops supplying the nitrogen gas. Then, the first opening/closing valve 421a and the second opening/closing valve 424a are closed, completing the oxygen-free environment creating step.

In the oxygen-free environment creating step, according to the second embodiment, as the chamber 4A is filled with the nitrogen gas to make itself free of oxygen, the chamber 4A can easily be made free of oxygen within a short period of time.

(5-2) Thermosetting Step According to Second Embodiment

In a thermosetting step according to a second embodiment, the built-in infrared heater 470 that is supplied with electric power from a power supply 479 illustrated in FIG. 9 radiates a far-infrared ray 43 upwardly. The far-infrared ray 43 radiated from outside the chamber 4A is applied through the bottom plate 40 thereof to the wafer W, heating the wafer W. The photosensitive thermosetting resin J1 is thermoset to form an insulating layer by the heat of the heated wafer W.

During the thermosetting step, the inactive gas supply source 48 may continuously supply the nitrogen gas to the chamber 4A.

When photosensitive thermosetting resin J1 has been thermoset to form an insulating layer on the wafer W, the infrared heater 470 stops heating the wafer W. The chamber 4A that has been hermetically sealed to keep itself free of oxygen is added to and cooled in a stack of similar chambers 4A that accommodate therein respective wafers W with insulating layers formed thereon. The stack of chambers 4A thus cooled together is preferable as it is a space saver and allows the chamber rest table 47 to be used for supporting another chamber 4A thereon, preventing the working efficiency from being lowered in a case where the chamber rest table 47 would otherwise be occupied to cool the wafer W thereon.

In the thermosetting step according to the second embodiment, as described above, the chamber 4A is made of quartz glass that can transmit the infrared ray 43 therethrough, the infrared ray 43 is applied from outside the chamber 4A to the wafer W in the chamber 4A to heat the wafer W, and the photosensitive thermosetting resin J1 is thermoset to form an insulating layer by the heat of the heated wafer W. Since the chamber 4A itself is not heated, the wafer W accommodated in the chamber 4A and having the insulating layer formed by thermosetting the photosensitive thermosetting resin J1 can be moved together with the chamber 4A without the need for cooling the chamber 4A. Accordingly, the entire process of forming the insulating layer is made efficient.

In a case where the wafer W is heated to thermoset the photosensitive thermosetting resin J1 according to the second embodiment, the infrared heater 470 may be disposed on the upper side of the chamber 4A.

The wafer W which has been cooled to normal temperature, for example, is then taken out of the chamber 4A and delivered to a sputtering apparatus, not illustrated, for forming a second interconnect layer on the wafer W.

The method of forming an insulating layer according to the present invention on the first interconnect layer L1 on the upper surface W2a of the wafer W is not limited to the above embodiments. The various apparatuses used in the method of forming an insulating layer according to the present invention are not limited to the illustrated details according to the embodiments, but may be changed or modified within the scope of the invention insofar as the advantages of the present invention are attainable.

For example, the oxygen-free environment creating step according to the first embodiment and the thermosetting step according to the second embodiment may be combined with each other, and the oxygen-free environment creating step according to the second embodiment and the thermosetting step according to the first embodiment may be combined with each other.

The photosensitive thermosetting resin J1 is thermoset when heated to a temperature in a range from 230° C. to 400° C. The chambers 4 and 4A are evacuated to a vacuum in a range from −85 kPa to −100 kPa.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of forming an insulating layer on a first interconnect layer formed on an upper surface of a wafer, comprising:
a coating step of coating an upper surface of the first interconnect layer and the upper surface of the wafer with a photosensitive thermosetting resin;
a modifying step of modifying predetermined regions of the photosensitive thermosetting resin into modified resin portions by irradiating the predetermined regions with light;
a removing step of dissolving the modified resin portions modified in the modifying step with a chemical solution that is supplied thereto to dissolve the modified resin portions and thereafter removing the dissolved modified resin portions by supplying a cleaning fluid to the wafer;
an oxygen-free environment creating step of accommodating the wafer from which the dissolved modified resin portions have been removed in the removing step into a hermetically sealable chamber, hermetically sealing the chamber, and making the chamber free of oxygen; and
a thermosetting step of heating the wafer accommodated in the chamber that has been made free of oxygen in the oxygen-free environment creating step to thermoset the photosensitive thermosetting resin, thereby forming an insulating layer.

2. The method of forming an insulating layer according to claim 1,
wherein, in the oxygen-free environment creating step, the chamber is evacuated to be free of oxygen.

3. The method of forming an insulating layer according to claim 1,
wherein, in the oxygen-free environment creating step, the chamber is filled with an inactive gas to be free of oxygen.

4. The method of forming an insulating layer according to claim 1,
wherein, in the thermosetting step, the chamber is heated to heat the wafer, the photosensitive thermosetting resin is thermoset with the heat of the heated wafer, and the insulating layer is thereby formed.

5. The method of forming an insulating layer according to claim 2,
wherein, in the thermosetting step, the chamber is heated to heat the wafer, the photosensitive thermosetting resin is thermoset with the heat of the heated wafer, and the insulating layer is thereby formed.

6. The method of forming an insulating layer according to claim 3,
wherein, in the thermosetting step, the chamber is heated to heat the wafer, the photosensitive thermosetting resin is thermoset with the heat of the heated wafer, and the insulating layer is thereby formed.

7. The method of forming an insulating layer according to claim 1,
wherein, in the thermosetting step, the chamber is made of quartz glass through which an infrared ray passes, an infrared ray is applied from outside the chamber to the wafer in the chamber to heat the wafer with the applied infrared ray, the photosensitive thermosetting resin is thermoset with the heat of the heated wafer, and the insulating layer is thereby formed.

8. The method of forming an insulating layer according to claim 2,
wherein, in the thermosetting step, the chamber is made of quartz glass through which an infrared ray passes, an infrared ray is applied from outside the chamber to the wafer in the chamber to heat the wafer with the applied infrared ray, the photosensitive thermosetting resin is thermoset with the heat of the heated wafer, and the insulating layer is thereby formed.

9. The method of forming an insulating layer according to claim 3,
wherein, in the thermosetting step, the chamber is made of quartz glass through which an infrared ray passes, an infrared ray is applied from outside the chamber to the wafer in the chamber to heat the wafer with the applied infrared ray, the photosensitive thermosetting resin is thermoset with the heat of the heated wafer, and the insulating layer is thereby formed.
